(19) United States
(12) Patent Application Publication
(10) Pub. No.: US 2021/0399215 A1
(43) Pub. Date: Dec. 23, 2021

(54) ETCHING METHOD FOR SINGLE-ISOLATED MAGNETIC TUNNEL JUNCTION

(71) Applicant: JIANGSU LEUVEN INSTRUMENTS CO. LTD, Xuzhou, Jiangsu (CN)

(72) Inventors: Dongdong HU, Jiangsu (CN); Juebin WANG, Jiangsu (CN); Zhongyuan JIANG, Jiangsu (CN); Ziming LIU, Jiangsu (CN); Dongchen CHE, Jiangsu (CN); Hushan CUI, Jiangsu (CN); Lu CHEN, Jiangsu (CN); Huiqun REN, Jiangsu (CN); Hongyue SUN, Jiangsu (CN); Kaidong XU, Jiangsu (CN)

(21) Appl. No.: 17/289,548

(22) PCT Filed: May 23, 2019
(86) PCT No.: PCT/CN2019/088145

§ 371 Date: Apr. 28, 2021

(30) Foreign Application Priority Data
Nov. 2, 2018 (CN) 201811298691.2

(51) Int. Cl. H01L 43/12; H01L 43/10; H01L 43/02; H01L 27/22; G11C 11/16

(52) U.S. Cl. CPC H01L 43/12; H01L 43/10; G11C 11/161; H01L 27/222; H01L 43/02

(57) ABSTRACT

A method for etching magnetic tunnel junction of single isolation layer, using an etching apparatus including a sample loading chamber, a vacuum transition chamber, a reactive ion etching chamber, an ion beam etching chamber, a coating chamber, and a vacuum transmission chamber, is applicable for the reactive ion etching chamber, ion beam etching chamber and coating chamber to process and treat a wafer according to specific steps without interrupting a vacuum. It can effectively alleviate the influence of masking effect in the production process of high-density small devices. Furthermore, the combined use of the ion beam etching chamber and the reactive ion etching chamber greatly reduces metal contaminations and damage on the film structure of the magnetic tunnel junction, greatly improves the performance and reliability of the devices, overcomes the technical problems existing in a single etching process in the art, and improves production efficiency and etching process accuracy

### TECHNICAL FIELD

The disclosure relates to the field of magnetic random access memory, in particular to a method for etching magnetic tunnel junction of single isolation layer.

### BACKGROUND OF THE INVENTION

As the feature size of semiconductor devices is further reduced in proportion, traditional flash memory technology will reach the limit of size. In order to further improve the performance of a device, R&D personnel began to actively explore new structures, new materials, and new processes. In recent years, various new types of non-volatile memories have been rapidly developed. Among them, magnetic random access memory (MRAM) has drawn more and more attention in the industry and is considered to be a very likely replacement for static random access memory (SRAM), dynamic random access memory (DRAM), and flash memory (FLASH) to become one of the strong candidates for the next generation of “universal” memory, because of the advantages including high-speed reading and writing capabilities as static random access memory, high integration density as dynamic random access memory, much lower power consumption than dynamic random access memory, and no performance degradation with time in comparison to flash memory. The industry and scientific research institutions have been committed to optimizing circuit design, technological process and integration solutions to obtain magnetic random access memory devices that can be successfully commercialized.

Magnetic tunnel junction (MTJ) is the core structure of magnetic random access memory. A main process of patterning the magnetic tunnel junction is still etching process. The material of the magnetic tunnel junction is Fe, Co, Mg, etc., which are difficult to be dry etched, and difficult to form volatile products, and for which corrosion gas (Cl₂, etc.) cannot be used, otherwise it will affect the performance of the magnetic tunnel junction, so more complicated etching process is needed. The etching process is very difficult and challenging. Traditional large-scale magnetic tunnel junction etching is done by ion beam etching. Since ion beam etching uses inert gas, basically no chemical etching components are introduced into the reaction chamber, so that the sidewall of the magnetic tunnel junction is not corroded by chemical reactions. In the case that the sidewall is clean, ion beam etching can obtain a relatively perfect magnetic tunnel junction sidewall, which is clean and not chemically damaged. However, ion beam etching also has its imperfections. On the one hand, one of the principles for the ion beam etching to be realized is to use high physical bombardment; however, excessive physical bombardment will disturb atomic layer ordering of the sidewall of the magnetic tunnel junction, especially for the isolation layer and its nearby core layer, thereby destroying magnetic characteristics of the magnetic tunnel junction. On the other hand, ion beam etching uses a certain angle to achieve etching, which brings limitations to ion beam etching. As the size of the magnetic tunnel junction device becomes smaller and smaller, the commonly used angle of ion beam etching cannot reach the bottom of the magnetic tunnel junction, thus failing to meet the requirement for separation of the magnetic tunnel junction device, causing failure in patterning. Furthermore, the time for ion beam etching is relatively long, and the yield of each piece of equipment is limited.

### SUMMARY OF THE INVENTION

In order to solve the above problems, embodiments of the present invention disclose a method for etching magnetic tunnel junction of single isolation layer. The etching apparatus used comprises a sample loading chamber, a vacuum transition chamber, a reactive ion etching chamber, an ion beam etching chamber, a coating chamber and a vacuum transmission chamber, wherein the vacuum transition chamber is respectively connected with the sample loading chamber and the vacuum transmission chamber in a communicable manner, the reactive ion etching chamber, the ion beam etching chamber and the coating chamber are respectively connected to the vacuum transmission chamber in a communicable manner. The method is applicable for the reactive ion etching chamber, the ion beam etching chamber and the coating chamber to treat and process a wafer without interrupting a vacuum, and comprises the following steps: a sample preparation step of forming a structure to be etched including a bottom electrode layer, a magnetic tunnel junction, a cap layer and a mask layer on a semiconductor substrate, wherein the magnetic tunnel junction comprises a pinned layer, a free layer, and an isolation layer; a sample loading step of loading the sample into the sample loading chamber and passing the sample through the vacuum transition chamber to the vacuum transmission chamber; a reactive ion etching step of bringing the sample into the reactive ion etching chamber and etching the sample by a reactive ion etching process until the free layer or the isolation layer is reached, and then returning the sample to the vacuum transmission chamber; a ion beam etching step of transmitting the sample from the vacuum transmission chamber to the ion beam etching chamber and etching the sample by an ion beam etching method until the bottom electrode is reached; a first ion beam cleaning step of maintaining the sample in the ion beam etching chamber and removing with ion beams metal contamination and sidewall damage produced in the reactive ion etching step and the ion beam etching step, and then returning the sample back into the vacuum transmission chamber; a protection step of bringing the sample into the coating chamber and performing coating protection on the upper surface and the periphery of the sample that has been etched, and then returning the sample back into the vacuum transmission chamber; and a sample taking step of returning the sample from the vacuum transmission chamber through the vacuum transition chamber to the sample loading chamber.

In the method for etching magnetic tunnel junction of single isolation layer of the present invention, preferably, between the reactive ion etching step and the ion beam etching step, there is a second ion beam cleaning step of transmitting the sample from the vacuum transmission chamber to the ion beam etching chamber, and removing with ion beams metal contaminations and sidewall damage produced in the reactive ion etching step, and then returning the sample to the vacuum transmission chamber.

In the method for etching magnetic tunnel junction of single isolation layer of the present invention, it is preferable that the magnetic tunnel junction has a structure in which the pinned layer is above the isolation layer, or the pinned layer is below the isolation layer.

In the method for etching magnetic tunnel junction of single isolation layer of the present invention, preferably, in the reactive ion etching step, a gas used comprises inert gas, nitrogen, oxygen, fluorine-based gas, NH₃, amino gas, CO, CO₂, alcohols or combinations thereof.

In the method for etching magnetic tunnel junction of single isolation layer of the present invention, preferably, in the ion beam etching step, a gas used comprises inert gas, nitrogen, oxygen or combinations thereof.

In the method for etching magnetic tunnel junction of single isolation layer of the present invention, preferably, in the protection step, a coating film is a dielectric material that separates adjacent magnetic tunnel junction devices.

In the method for etching magnetic tunnel junction of single isolation layer of the present invention, preferably, the dielectric material is Group IV oxide, Group IV nitride, Group IV oxynitride, transition metal oxide, transition metal nitride, transition metal oxynitrides, alkaline earth metal oxides, alkaline earth metal nitrides, alkaline earth metal oxynitrides, or combinations thereof.

In the method for etching magnetic tunnel junction of single isolation layer of the present invention, it is preferable that a thickness of the coating film is 1 nm to 500 nm.

The invention can effectively address the influence of masking effect in the process of production of high-density small devices. In addition, the combined use of the ion beam etching chamber and the reactive ion etching chamber greatly reduces metal contamination and damage in the film structure of magnetic tunnel junction, greatly improves the performance and reliability of the device, overcomes the technical problems of a single etching method in the prior art and improves production efficiency and etching process accuracy.

### BRIEF DESCRIPTION OF THE DRAWINGS

FIG. 1 is a functional block diagram of an etching apparatus used in a method magnetic tunnel junction of single isolation layer of the present invention.

FIG. 2 is a flowchart of a first embodiment of the method for etching magnetic tunnel junction of single isolation layer of the present invention.

FIG. 3 is a schematic diagram of the structure of a device to be etched, in which a pinned layer of a magnetic tunnel junction is below the isolation layer.

FIG. 4 is a schematic diagram of a device structure formed after a reactive ion etching step.

FIG. 5 is a schematic diagram of a device structure formed after an ion beam etching step.

FIG. 6 is a schematic diagram of a device structure formed after a first ion beam cleaning step.

FIG. 7 shows the morphology of a sidewall of the magnetic tunnel junction with different cleaning process parameters: (a) 90° C.<α<130° C., (b) α<90° C., (c) α<60° C.

FIG. 8 is a schematic diagram of a device structure formed after the protection step.

FIG. 9 is a flowchart of a second embodiment of the method for etching magnetic tunnel junction of single isolation layer of the present invention.

FIG. 10 is another schematic diagram of the structure of a device to be etched, in which the pinned layer of the magnetic tunnel junction is above the isolation layer.

### DETAILED DESCRIPTION OF THE INVENTION

In order to make the objectives, technical solutions, and advantages of the present invention clearer, the following will clearly and completely describe the technical solutions in the embodiments of the present invention with reference to the accompanying drawings in the embodiments of the present invention. It should be understood that the specific embodiments described herein are only used to explain the present invention, but not used to limit the present invention. The described embodiments are only a part of the embodiments of the present invention, rather than all the embodiments. Based on the embodiments of the present invention, all other embodiments obtained by those of ordinary skill in the art without creative work shall fall within the protection scope of the present invention.

In the description of the present invention, it should be noted that the orientation or positional relationship indicated by the terms “upper”, “lower”, “steep”, “inclined”, etc. are based on the orientation or positional relationship shown in the drawings, and only in order to facilitate the description of the present invention and simplify the description, rather than indicating or implying that the indicated device or element must have a specific orientation, be constructed and operated in a specific orientation, and therefore cannot be understood as a limitation to the present invention. In addition, the terms “first” and “second” are only used for descriptive purposes, and cannot be understood as indicating or implying relative importance.

In addition, many specific details of the present invention are described below, such as the structure, materials, dimensions, treating process and technology of a device, in order to understand the present invention more clearly. However, as those skilled in the art can understand, the present invention may not be implemented according to these specific details. Unless specifically indicated in the following, each part of the device may be composed of materials known to those skilled in the art, or materials with similar functions developed in the future may be used.

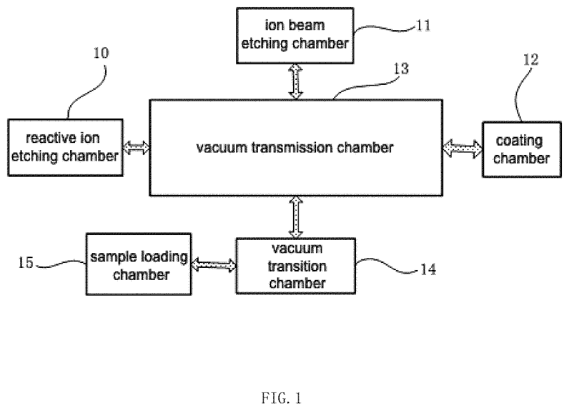

Hereinafter, an apparatus used in a method for etching magnetic tunnel junction of single isolation layer of the present invention will be described with reference to the accompanying drawings. FIG. 1 is a functional block diagram of the etching apparatus used in the method for etching magnetic tunnel junction of single isolation layer of the present invention. As shown in FIG. 1, the etching apparatus comprises a reactive ion etching chamber 10, an ion beam etching (IBE) chamber 11, a coating chamber 12, a vacuum transmission chamber 13, a vacuum transition chamber 14 and a sample loading chamber 15. The vacuum transition chamber 14 is respectively connected with the sample loading chamber 15 and the vacuum transmission chamber 13 in a communicable manner. The reactive ion etching chamber 10, the ion beam etching chamber 11, and the coating chamber 12 are respectively connected with the vacuum transmission chamber 13 in a communicable manner. In addition, there may be a plurality of each of the above-mentioned chambers.

The reactive ion etching chamber 10 may be a reactive ion etching chamber such as an inductively coupled plasma (ICP) chamber, a capacitively coupled plasma (CCP) chamber, or a spiral wave plasma chamber. The ion beam etching (IBE) chamber 11 may be an ion beam etching, a neutral particle beam etching chamber, or the like. The coating chamber 12 can be a physical vapor deposition (PVD) coating chamber, or a chemical vapor deposition (CVD) coating chamber such as a pulsed chemical vapor deposition (Pulsed CVD) coating chamber, a plasma enhanced chemical vapor deposition (PECVD) coating chamber, an inductively coupled plasma enhanced chemical vapor deposition (ICP-PECVD) coating chamber, and an atomic layer (ALD) coating chamber.

In addition, the etching apparatus also comprises functional units comprised in a conventional etching apparatus, such as a sample transmission system for realizing transmission of samples in different chambers, a control system for controlling each chamber and the sample transmission system, etc., a vacuum pumping system for realizing a vacuum degree required for each chamber, and a cooling system. These apparatus structure can be implemented by those skilled in the art using existing technology.

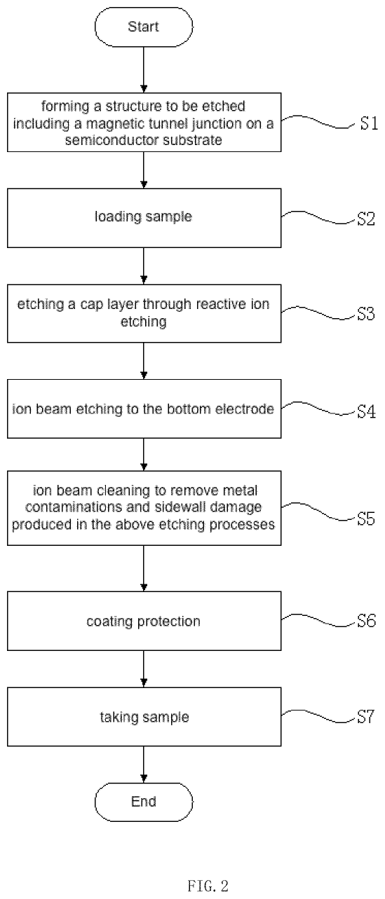

As shown in FIG. 2, a first embodiment of the method for etching magnetic tunnel junction of single isolation layer of the present invention is implemented by the following steps. First, in a sample preparation step S1, a structure to be etched including a magnetic tunnel junction is formed on the semiconductor substrate. FIG. 3 shows a schematic diagram of the structure of a device to be etched. As shown in FIG. 3, the structure to be etched comprises a bottom electrode layer 100, a magnetic tunnel junction (including a pinned layer 101, an isolation layer 102 and a free layer 103), a cap layer 104 and a hard mask layer 105.

Next, in a sample loading step S2, the sample is loaded into the sample loading chamber 15, and the sample is passed through the vacuum transition chamber 14 into the vacuum transmission chamber 13.

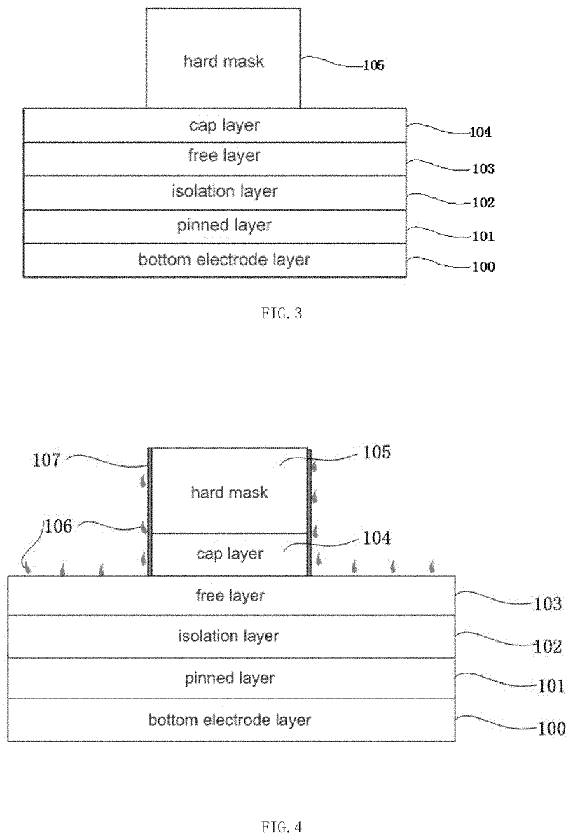

Next, in a reactive ion etching step S3, the sample is brought into the reactive ion etching chamber 10 to be etched by reactive ion plasma. When the etching of the cap layer 104 is completed, the etching is stopped. The sample is then returned to the vacuum transmission chamber 13. The gas used in the reactive ion etching chamber can be inert gas, nitrogen, oxygen, fluorine-based gas, NH₃, amino gas, CO, CO₂, alcohols, etc. The etching process must realize the separation of the device and the required steepness of the device. No metal contamination is the target for the sidewall of the device formed by etching, though a very small amount of metal contamination, such as less than 1 nm, is difficult to completely avoid. At the same time, a nano-scale damage layer on the sidewall of the magnetic tunnel junction may be formed during the etching process. FIG. 4 is a schematic diagram of a device structure formed after the reactive ion etching step. FIG. 4 schematically shows metal contaminations 106 and a damage layer 107 on the sidewall of the magnetic tunnel junction formed during the plasma etching process. After the patterning of the cap layer is finished by reactive ion etching, the mask layer is usually consumed somewhat. At this time, the aspect ratio of the overall device (including the mask layer) has decreased, which enables the etching and cleaning process in the subsequent ion beam etching chamber to be carried out at a relatively large inclined angle; especially, after the overall etching process is completed, the entire device sidewall is subjected to complete cleaning and surface treating. This can alleviate the effect of the masking effect during the production process of high-density (such as 1:1 spacing) small devices (20 nm and below).

Next, in an ion beam etching step S4, the sample is brought into the ion beam etching chamber 11 to be etched continuously by ion beam etching, and the etching is stopped when it reaches the bottom electrode. The resulting structure is shown in FIG. 5. A gas for ion beam etching can be inert gas, nitrogen, oxygen, etc. An angle used for ion beam etching is preferably 10 degrees to 80 degrees, and the angle is an angle between an ion beam and a normal surface of a sample stage.

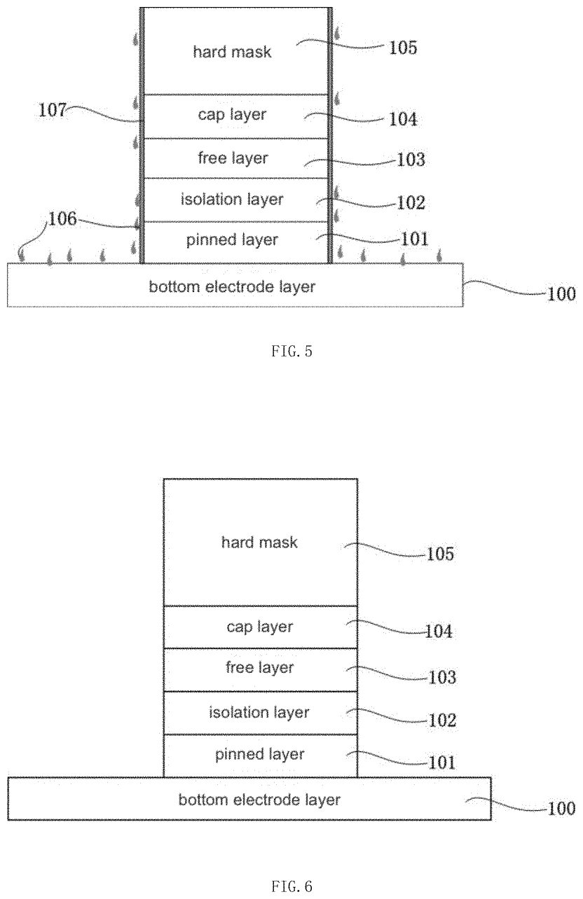

Next, in a first ion beam cleaning step S5, the sample is kept in the ion beam etching chamber 11 to remove metal residues and perform sample surface treatment with ion beams, to completely remove the sidewall metal contaminations and sidewall damage layer formed in the above-mentioned reactive ion etching step and ion beam etching step are completely removed; and at the same time, to completely remove the metal contaminations above the bottom electrode of the device and above the dielectric layer between the bottom electrodes of different devices, so as to achieve complete electrical isolation between the devices and avoid short circuit between the devices. The sample is then returned to the vacuum transmission chamber 13. A gas used in the ion beam cleaning step can be inert gas, nitrogen, oxygen, etc., which may be the same as or different from the gas used in the ion beam etching step; an etching angle of ion beams, energy and density of ion beams can also be the same or different. Preferably, the sidewall of the magnetic tunnel junction is removed by 0.1 nm to 5.0 nm. After the device undergoes the above-mentioned etching steps in two chambers, the sidewall of the device is clean and devices are completely separated. FIG. 6 shows a schematic diagram of a device structure formed after the first ion beam cleaning step.

After the above-mentioned overall etching process is completed, the aspect ratio of the entire device is reduced. The ion beam cleaning in this step can use a relatively large inclination angle to completely clean and surface-treat the sidewall of the overall device. In addition, through the adjustment of process parameters in the ion beam cleaning, a steep sidewall profile can be achieved, which significantly improves the yield and reliability of the device. At the same time, in the removal process of the bottom metal contaminations, in case that a certain amount of over-etching of the bottom electrode layer is allowed, the reliability and yield of the device can be significantly improved. According to different cleaning process parameters, there may be occurred three types of morphologies for the sidewall of the magnetic tunnel junction, as shown in FIG. 7. In the first case, an angle α between the sidewall of the magnetic tunnel junction and the surface of the bottom electrode metal layer or the dielectric layer assumes an angle greater than 90°, and the angle does not exceed 130° at the maximum; in the second case, under appropriate cleaning process parameters, an angle α between the sidewall of the magnetic tunnel junction and the surface of the bottom electrode metal layer or dielectric layer assumes 90°; in the third case, an angle α between the sidewall of the magnetic tunnel junction and the bottom surface assumes an angle less than 90°, and the minimum angle is not less than 60°. By adjusting the cleaning process parameters, it is possible to control the morphology of the sidewall in terms of steepness as a result of etching, and obtain an upright or nearly upright sidewall morphology.

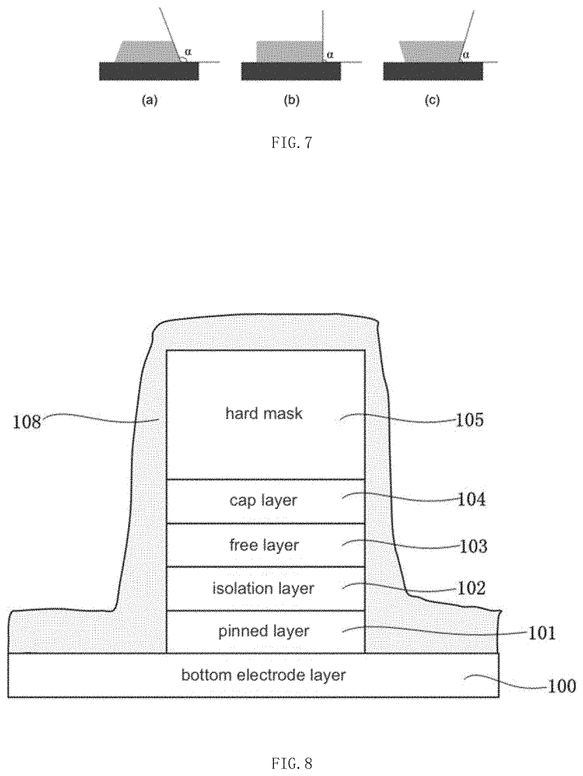

Next, in a protection step S6, the sample is brought into the coating chamber 12, and a coating is performed on the upper surface and the periphery of a etched sample for protection, and then the sample is returned to the vacuum transmission chamber 13. A schematic diagram of a device structure after the protection step is shown in FIG. 8. In the figure, a dielectric film 108 is a dielectric material that separates adjacent magnetic tunnel junction devices, such as group IV oxides, group IV nitrides, group IV oxynitrides, transition metal oxides, transition nitrides, transition oxynitrides, alkaline earth metal oxides, alkaline earth nitrides, alkaline earth oxynitrides, etc. A thickness of a coating film can be 1 nm or more and 500 nm or less. The in-situ coating protection in the coating chamber can prevent the device from being damaged by being exposed to the atmosphere in the subsequent process, and at the same time realize complete insulation and isolation between devices.

Finally, in a sample taking step S7, the sample is returned from the vacuum transmission chamber 13 to the sample loading chamber 15 through the vacuum transition chamber 14.

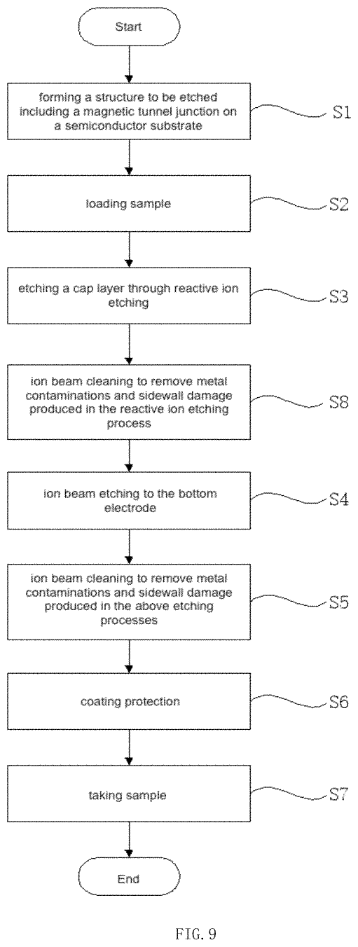

A second embodiment of the present invention is basically the same as the first embodiment The difference is that between the reactive ion etching step S3 and the ion beam etching step S4, a second ion beam cleaning step 88 is further included, as shown in FIG. 9, in which the sample is transmitted from the vacuum transmission chamber 13 to the ion beam etching chamber 11, where the metal contaminations and sidewall damage produced in the reactive ion etching step are removed with ion beams, and then the sample is returned to the vacuum transmission chamber 13. By adding this process step, the influence of the defects left by the reactive ion etching process on a subsequent etching process of a core layer of the magnetic tunnel junction can be further reduced. The other steps are the same as in the first embodiment, and will not be repeated here.

A third embodiment of the present invention is basically the same as the first embodiment. The difference is that in the reactive ion etching step S3, the sample is brought into the reactive ion etching chamber 10 to be etched with reactive ion plasma, and the etching is stopped when the etching of the cap layer 104 and the free layer 103 is completed and the isolation layer 102 is reached. The other steps are the same as in the first embodiment, and will not be repeated here. After the reactive ion etching reaches the isolation layer, the mask layer is usually consumed somewhat. At this time, the aspect ratio of the overall device (including the mask layer) is reduced, which enables the subsequent etching and cleaning process in the ion beam etching chamber to be carried out at a relatively large inclined angle; especially, after the overall etching process is completed, a complete cleaning and surface-treatment can be performed on the entire device sidewall. In addition, since the core layer of the magnetic tunnel junction located under the isolation layer is etched by ion beam etching and does not appear in the chemical gas atmosphere of reactive ion etching, the entire process minimizes a damage of chemical gas to the device and the film structure of the device, so that a device of higher performance can be obtained.

A fourth embodiment of the present invention is basically the same as the second embodiment. The difference is that in the reactive ion etching step S3, the sample is brought into the reactive ion etching chamber 10 to be etched by reactive ion plasma, and the etching is stopped when the etching of the cap layer and the free layer is completed and the isolation layer is reached. The other steps are the same as in the second embodiment, and will not be repeated here.

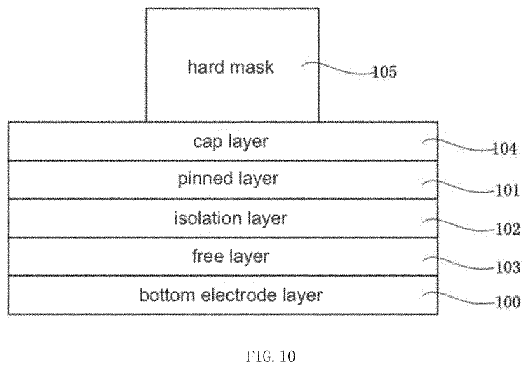

In the above description, the specific embodiments of the magnetic tunnel junction etching method of the present invention have been described in detail, but the present invention is not limited to thereto. The specific implementation of each step can be different according to the situation. In addition, the order of some steps can be exchanged, and some steps can be omitted. It should be noted that the structure of the above-mentioned magnetic tunnel junction is only an example. In actual device applications, the constitution of the magnetic tunnel junction can also be such that the free layer is below the isolation layer, and the pinned layer is above the isolation layer, as shown in FIG. 10. The method for fabricating a single isolation layer magnetic tunnel junction of the present invention is also applicable to these different structures.

The above are only specific embodiments of the present invention, but the scope of protection of the present invention is not limited thereto. Any changes or substitutions occurred to those skilled in the art within the technical scope disclosed by the present invention should all be covered within the protection scope of the present invention.

1. A method for etching magnetic tunnel junction of single isolation layer, using an etching apparatus including a sample loading chamber, a vacuum transition chamber, a reactive ion etching chamber, an ion beam etching chamber, a coating chamber, and a vacuum transmission chamber, wherein, the vacuum transition chamber is respectively connected with the sample loading chamber and the vacuum transmission chamber in a communicable manner, the reactive ion etching chamber, the ion beam etching chamber, and the coating chamber are respectively connected with the vacuum transmission chamber in a communicable manner; the method being applicable for the reactive ion etching chamber, the ion beam etching chamber, and the coating chamber to treat and process a wafer without interrupting a vacuum; and the method comprising the following steps:
a sample preparation step of forming on a semiconductor substrate a structure to be etched including a bottom electrode layer, a magnetic tunnel junction, a cap layer and a mask layer, the magnetic tunnel junction including a pinned layer, a free layer and an isolation layer;
a sample loading step of loading the sample into the sample loading chamber, and passing the sample through the vacuum transition chamber to the vacuum transmission chamber;
a reactive ion etching step of bringing the sample into the reactive ion etching chamber and etching the sample through a reactive ion etching process until the free layer or the isolation layer is reached, and then returning the sample back to the vacuum transmission chamber;
an ion beam etching step of transmitting the sample from the vacuum transmission chamber to the ion beam etching chamber and etching the sample through an ion beam etching process until the bottom electrode is reached;
a first ion beam cleaning step of maintaining the sample in the ion beam etching chamber to remove, with ion beams, metal contaminations and sidewall damage produced in the reactive ion etching step and the ion beam etching step, and then returning the sample back to the vacuum transmission chamber;
a protection step of bringing the sample into the coating chamber to perform coating on the upper surface and periphery of a etched sample for protection, and then returning the sample back to the vacuum transmission chamber; and
a sample taking step of returning the sample from the vacuum transmission chamber through the vacuum transition chamber to the sample loading chamber.

2. The method for etching magnetic tunnel junction of single isolation layer according to claim 1, wherein:
between the reactive ion etching step and the ion beam etching step, a second ion beam cleaning step is further included, in which the sample is transmitted from the vacuum transmission chamber to the ion beam etching chamber where the metal contaminations and the sidewall damage produced in the reactive ion etching step are removed with ion beams, and then the sample is returned back to the vacuum transmission chamber.

3. The method for etching magnetic tunnel junction of single isolation layer according to claim 2, wherein
the magnetic tunnel junction has a structure in which the pinned layer is above the isolation layer, or the pinned layer is below the isolation layer.

4. The method for etching magnetic tunnel junction of single isolation layer according to claim 2, wherein
in the reactive ion etching step, a gas used comprises inert gas, nitrogen, oxygen, fluorine-based gas, NH₃, amino gas, CO, CO₂, alcohols or combinations thereof.

5. The method for etching magnetic tunnel junction of single isolation layer according to claim 2, wherein
in the ion beam etching step, a gas used comprises inert gas, nitrogen, oxygen, or combinations thereof.

6. The method for etching magnetic tunnel junction of single isolation layer according to claim 2, wherein
in the protection step, a coating film is a dielectric material that separates adjacent magnetic tunnel junction devices.

7. The method for etching magnetic tunnel junction of single isolation layer according to claim 6, wherein:
the dielectric material is Group IV oxide, Group IV nitride, Group IV oxynitride, transition metal oxide, transition metal nitride, transition metal oxynitride, alkaline earth metal oxide, alkaline earth metal nitride, alkaline earth metal oxynitrides or combinations thereof.

8. The method for etching magnetic tunnel junction of single isolation layer according to claim 6, wherein:
the coating film has a thickness of 1 nm˜500 nm.

9. The method for etching magnetic tunnel junction of single isolation layer according to claim 1, wherein
the magnetic tunnel junction has a structure in which the pinned layer is above the isolation layer, or the pinned layer is below the isolation layer.

10. The method for etching magnetic tunnel junction of single isolation layer according to claim 1, wherein
in the reactive ion etching step, a gas used comprises inert gas, nitrogen, oxygen, fluorine-based gas, NH₃, amino gas, CO, CO₂, alcohols or combinations thereof.

11. The method for etching magnetic tunnel junction of single isolation layer according to claim 1, wherein
in the ion beam etching step, a gas used comprises inert gas, nitrogen, oxygen, or combinations thereof.

12. The method for etching magnetic tunnel junction of single isolation layer according to claim 1, wherein
in the protection step, a coating film is a dielectric material that separates adjacent magnetic tunnel junction devices.

13. The method for etching magnetic tunnel junction of single isolation layer according to claim 12, wherein:
the dielectric material is Group IV oxide, Group IV nitride, Group IV oxynitride, transition metal oxide, transition metal nitride, transition metal oxynitride, alkaline earth metal oxide, alkaline earth metal nitride, alkaline earth metal oxynitrides or combinations thereof.

14. The method for etching magnetic tunnel junction of single isolation layer according to claim 12, wherein:
the coating film has a thickness of 1 nm˜500 nm.
